(19) United States
(12) Patent Application Publication
(10) Pub. No.: US 2026/0082864 A1
(43) Pub. Date: Mar. 19, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventor: Fumihiko IKEDA, Kyoto-shi (JP)

(21) Appl. No.: 19/252,622

(22) Filed: Jun. 27, 2025

(30) Foreign Application Priority Data
Sep. 13, 2024 (JP) 2024-159189

(51) Int. Cl. H01L 21/683; H01L 21/67; H01L 21/687

(52) U.S. Cl. CPC H10P 72/78; H10P 72/0424; H10P 72/7618

(57) ABSTRACT

In the substrate processing apparatus and method according to the present invention, a suction region of a chuck body is surrounded by the annular elastic part of a packing. Before a lower surface center of a substrate and the suction region of the chuck body are held in close contact, the annular elastic part is deformed to follow and held in close contact with a lower surface of the substrate while surrounding the lower surface center of the substrate. Thus, suction leak hardly occurs, and the substrate is sucked and held by the suction region not only when the substrate is not warped, but also when the substrate is warped. Thus, the substrate can be processed with a processing liquid while being sucked and held with a suction force capable of sufficiently withstanding the rotation of the substrate.

### CROSS REFERENCE TO RELATED APPLICATION

The disclosure of Japanese Patent Application No. 2024-159189 filed on September 13, 2024 including specification, drawings and claims is incorporated herein by reference in its entirety.

### BACKGROUND OF THE INVENTION

### 1. Field of the Invention

This invention relates to a substrate processing apparatus and a substrate processing method for processing a substrate having a lower surface center thereof sucked and held by a chuck body by supplying a processing liquid to the upper surface of the substrate while rotating the substrate. Here, examples of substrates include semiconductor package substrates such as FOWLP (fan out wafer level package) substrates, glass substrates for liquid crystal display device, substrates for organic EL, semiconductor substrates, glass substrates for photomask, substrates for color filter, substrates for recording disc, substrates for solar cell, substrates for precision electronic device such as substrates for electronic paper, rectangular glass substrates and flexible substrates for film liquid crystal.

### 2. Description of the Related Art

A substrate processing apparatus is known in which a development processing is applied by supplying a processing liquid such as a development liquid to the upper surface of a substrate such as a semiconductor wafer while rotating the substrate. For example, in patent literature 1 (JP 2023-138049A), the substrate is held in a horizontal posture by a suction region provided on the upper surface of a sucking/holding part (corresponding to an example of a “chuck body” of the invention) sucking a lower surface center of the substrate. By operating a spin motor coupled to the sucking/holding part, the substrate rotates in the horizontal posture. The development liquid is supplied from a nozzle to the upper surface of the rotating substrate.

### SUMMARY OF INVENTION

In the apparatus for rotating the substrate while sucking and holding the substrate, it is important that a suction force for the substrate is satisfactorily maintained. If the substrate is rotated with the suction force kept low, a problem occurs in which the substrate is peeled off from the sucking/holding part by rotation. In a substrate to be relatively largely warped, for example, represented by a semiconductor package substrate, a lower surface center thereof can sufficiently follow the suction region of the sucking/holding part and the above problem may occur during the development processing. Further, if the followability is low, a suction error may occur and the development processing may have to be interrupted.

This invention was developed in view of the above problem and aims to provide a substrate processing apparatus and a substrate processing method capable of processing a substrate by a processing liquid while sucking and holding the substrate with a suction force capable of sufficiently withstanding the rotation of the substrate.

A first aspect of the invention is a substrate processing apparatus. The apparatus comprises: a chuck body having an upper surface with a suction region configured to suction and hold a lower surface center of a substrate, the chuck body being provided rotatably about an axis of rotation while sucking and holding the substrate in the suction region; a packing attached around the chuck body; a rotator having a motor configured to rotate the chuck body and the packing integrally about the axis of rotation; and a nozzle configured to supply a processing liquid to an upper surface of the substrate sucked and held on the chuck body, wherein the packing includes an externally fitting part externally fitted around the chuck body and an annular elastic part made of an elastic material and formed from the externally fitting part to project further upward than the upper surface of the chuck body and surround the suction region, and the annular elastic part is configured to deformed to follow and hold in close contact with a lower surface of the substrate while surrounding the lower surface center of the substrate.

A second aspect of the invention is a substrate processing method. The method comprises: (a) loading a substrate onto a packing and a chuck body; (b) sucking and holding the substrate on the chuck body; and (c) supplying a processing liquid to an upper surface of the substrate while rotating the chuck body, wherein: the packing includes an externally fitting part to be externally fitted around the chuck body and an annular elastic part made of an elastic material, projecting further upward than an upper surface of the chuck body from the externally fitting part and surrounding the suction region, and the annular elastic part is deformed to follow and held in close contact with a lower surface of the substrate while surrounding a lower surface center of the substrate in the operation (b).

In the invention thus configured, the substrate is sucked and held on the chuck body with the lower surface center of the substrate and the suction region of the chuck body held in close contact with each other. Here, if the substrate is, for example, warped, the suction region cannot follow the lower surface center of the substrate and suction leak may occur. However, in the invention, the suction region of the chuck body is surrounded by the annular elastic part of the packing. Before the lower surface center of the substrate and the suction region of the chuck body are held in close contact, the annular elastic part is deformed to follow and held in close contact with the lower surface of the substrate while surrounding the lower surface center of the substrate. Thus, suction leak hardly occurs, and the substrate is sucked and held by the suction region not only when the substrate is not warped, but also when the substrate is warped.

As described above, according to the invention, the substrate can be processed by the processing liquid while being sucked and held with a suction force capable of sufficiently withstanding the rotation of the substrate.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a plan view showing a schematic configuration of a substrate processing system equipped with an embodiment of a substrate processing apparatus according to the present invention.

FIG. 2A is a diagram showing the configuration of a first embodiment of the substrate processing apparatus according to the invention.

FIG. 2B is a plan view of a central part of FIG. 2A when viewed from above.

FIG. 3 is a diagram schematically showing the attachment of a packing to the spin base.

FIG. 4A shows a state immediately after the loading of the substrate by the substrate conveyor robot.

FIG. 4B shows a state immediately after the annular elastic part contacts the lowered substrate.

FIG. 4C shows a state when the transfer of the substrate to the spin base is completed.

FIG. 5 is a diagram showing the configuration of a second embodiment of the substrate processing apparatus according to the invention.

FIGS. 6A and 6B are diagrams showing the configuration of a third embodiment of the substrate processing apparatus according to the invention.

FIGS. 7A and 7B are diagrams showing the configuration of a fourth embodiment of the substrate processing apparatus according to the invention.

FIG. 8 is a diagram showing the configuration of a fifth embodiment of the substrate processing apparatus according to the invention.

FIG. 9 is a diagram showing the configuration of a sixth embodiment of the substrate processing apparatus according to the invention.

### DETAILED DESCRIPTION OF THE PREFERRED EMBODIMENTS

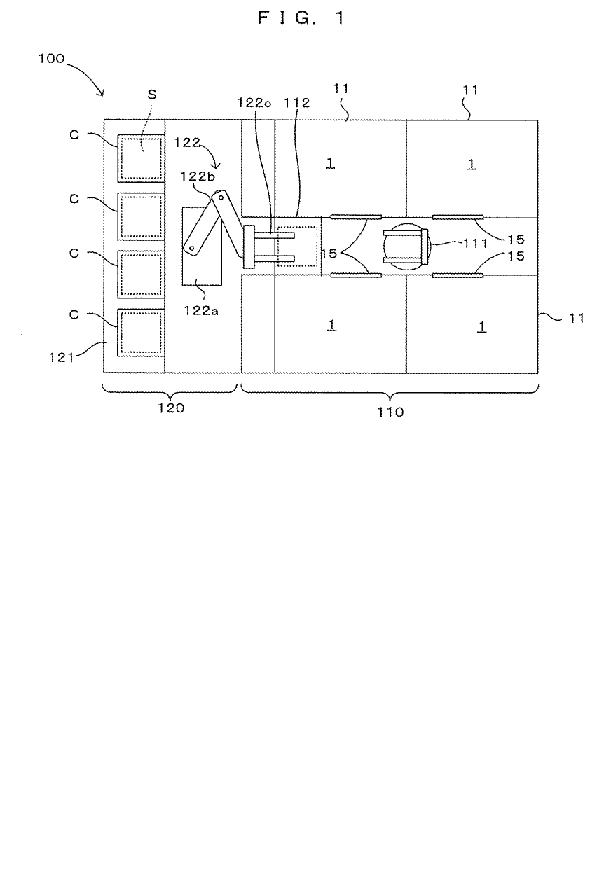

FIG. 1 is a plan view showing a schematic configuration of a substrate processing system equipped with an embodiment of a substrate processing apparatus according to the present invention. This figure is a diagram not showing the external appearance of the apparatus, but showing an internal structure of a substrate processing system 100 by excluding an outer wall panel and other partial configurations. This substrate processing system 100 is, for example, installed in a clean room and processes substrates S one by one.

The substrate processing system 100 includes a plurality of processing units (substrate processing apparatuses) 1 each principally responsible for a process on the substrate S. While FIG. 1 shows a state where four processing units 1 are arranged in a horizontal direction, the processing units 1 are also stacked in tiers in a top-bottom direction. If the processing units 1 are stacked in six tiers, for example, the substrate processing system 100 includes 24 processing units 1 in total.

Each of the plurality of processing units 1 equipped in the substrate processing system 100 receives the substrate S having a rectangular shape and performs a development processing by supplying a development liquid to the upper surface of the substrate S as described later. That is, the processing unit 1 corresponds to an example of the substrate processing apparatus 10 capable of carrying out one embodiment of a substrate processing method according to the invention.

As shown in FIG. 1, the substrate processing system 100 includes a substrate processing station 110 for processing the rectangular substrate S. An indexer station 120 is coupled to this substrate processing station 110. The indexer station 120 includes a container holder 121 capable of holding a plurality of containers C for housing the substrates S (FOUPs (Front Opening Unified Pods), SMIF (Standard Mechanical Interface) pods, OCs (Open Cassettes) for housing a plurality of the substrates S in a sealed state), and an indexer robot 122 for taking out an unprocessed substrate S from the container C by accessing the container C held by the container holder 121 and housing a processed substrate S in the container C. A plurality of the substrates S are housed substantially in a horizontal posture in each container C.

The indexer robot 122 includes a base 122a fixed to apparatus housing, an articulated arm 122b provided rotatably about a vertical axis with respect to the base 122a, and a hand 122c mounted on the tip of the articulated arm 122b. The hand 122c is structured such that the substrate S can be placed and held on the top surface thereof. Such an indexer robot including the articulated arm and the hand for holding the substrate is not described in detail since being known.

The substrate processing station 110 includes a mounting table 112 on which the indexer robot 122 places the substrate S. A substrate conveyor robot 111 is positioned substantially in a center in a plan view. A plurality of processing units 1 (substrate processing apparatuses 10) are arranged to surround this substrate conveyor robot 11. Specifically, the plurality of processing units 1 are arranged to face a space where the substrate conveyor robot 111 is arranged. The substrate conveyor robot 111 randomly accesses the mounting table 112 for these processing units 1 and transfers the substrate S to and from the mounting table 112. In the present embodiment, these processing units 1 (substrate processing apparatus 10) have the same function. Thus, a plurality of the substrates S can be processed in parallel. If the substrate conveyor robot 111 can directly transfer the substrate S from the indexer robot 122, the mounting table 112 is not necessarily required.

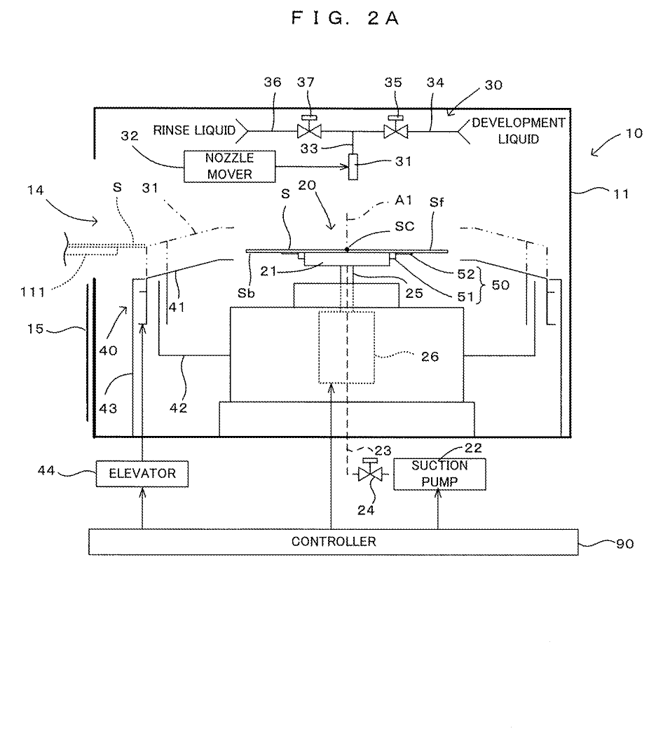

FIG. 2A is a diagram showing the configuration of a first embodiment of the substrate processing apparatus according to the invention. FIG. 2B is a plan view of a central part of FIG. 2A when viewed from above. In FIGS. 2A, 2B and figures to be described later, the dimensions and numbers of the respective components are shown in an exaggerated or simplified manner to facilitate understanding. The substrate processing apparatus 10 includes a box-shaped chamber 11 having an internal space.

A loading/unloading port 14, through which the substrate S is passed, is provided in a side wall of the chamber 11. Further, a shutter 15 for opening and closing the loading/unloading port 14 is attached to the side wall. For example, as shown in FIG. 2A, the substrate S is loaded into the chamber 11 via the loading/unloading port 14 with the shutter 15 opened. One substrate S is rotated about an axis of rotation A1 passing through and perpendicular to a center SC of the substrate S while being horizontally held by a spin base 21 of a spin chuck 20 in the chamber 11.

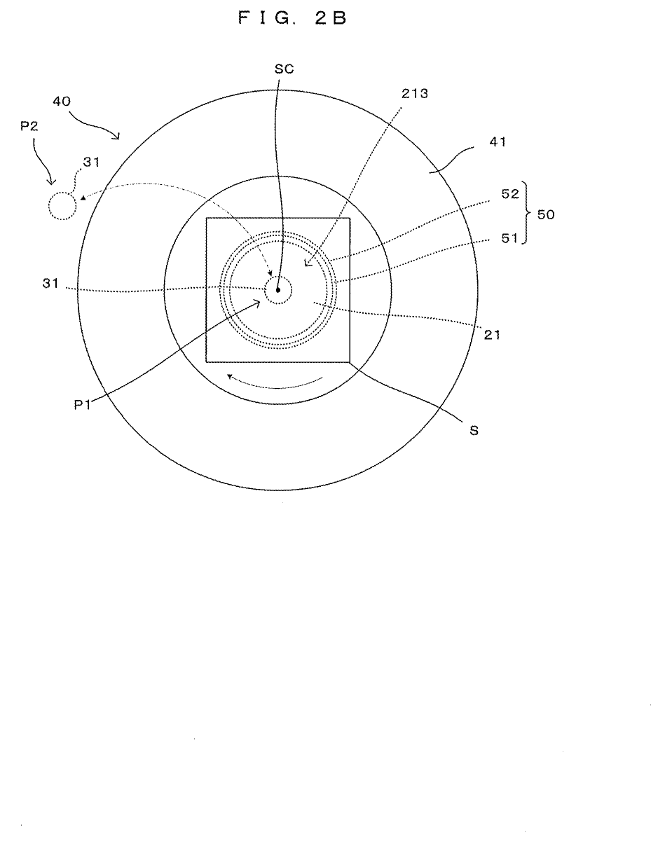

FIG. 3 is a diagram schematically showing the attachment of a packing to the spin base. In FIG. 3, the left figure is a perspective view showing the attachment. Further, the right figure is a side view showing the attachment, shows only a cross-sectional structure of the packing 50, whereas the other configuration is shown in a side view to clarify the operation of the packing 50. The spin chuck 20 includes the spin base 21 having a disk shape smaller than the substrate S and a suction pump 22. A plurality of suction grooves 212 are provided in an upper surface 211 of the spin base 21. The suction grooves 212 are connected to the suction pump 22 (FIG. 2A) by a suction pipe 23. A suction valve 24 is disposed in this suction pipe 23 as shown in FIG. 2A. Thus, the suction pump 22 operates in response to a command from a controller 90 for controlling the entire apparatus and the suction valve 24 is opened in response to a command from the controller 90, whereby a suction force of the suction pump 22 is transmitted to the suction grooves 212. As a result, a lower surface center of the substrate S faced to the spin base 21 is sucked to the spin base 21. In this way, the substrate S is horizontally held on the spin base 21. As just described, the spin base 21 corresponds to an example of a “chuck body” of the invention. Further, out of the upper surface 211 of the spin base 21, a region 213 where the suction grooves 212 are provided corresponds to an example of a “suction region” of the invention, and referred to as a “suction region 213” below.

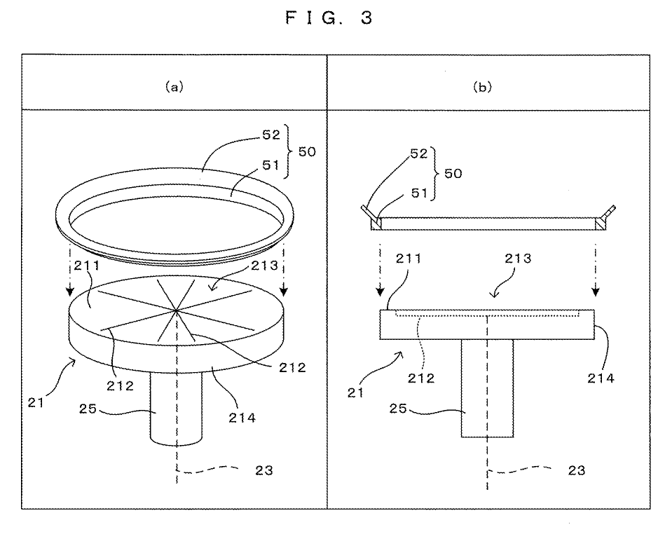

Further, in this embodiment, the packing 50 is attached around the spin base 21. This packing 50 includes an externally fitting part 51 to be externally fitted to a periphery 214 of the spin base 21 and an annular elastic part 52 projecting further upward than the upper surface 211 of the spin base 21 from the externally fitting part 51 and surrounding the suction region 213. In this embodiment, the externally fitting part 51 and the annular elastic part 52 are integrally molded from an elastic material such as rubber or resin. Thus, as shown in FIG. 3, the externally fitting part 51 is held in close contact with the periphery 214 of the spin base 21 by externally fitting the externally fitting part 51 to the spin base 21. Further, when the substrate S is loaded onto the spin base 21, the annular elastic part 52 is deformed to follow and held in close contact with a lower surface Sb of the substrate S while surrounding the lower surface center of the substrate S. Thus, suction leak from a space (see FIG. 4B) surrounding the lower surface center of the substrate S and the upper surface 211 of the spin base 21 by the packing 50 is suppressed. As a result, even if the substrate S is warped, the lower surface center of the substrate S can be held in close contact with the upper surface 211. Note that this point is described in detail later with reference to FIGS. 4A to 4C.

The spin chuck 20 includes a spin shaft 25 extending downward from a central part of the spin base 21 having the packing 50 attached thereto, a spin motor (rotator) 26 for rotating the spin shaft 25, the spin base 21 and the packing 50 about an axis of rotation A1 and a motor housing 27 for accommodating the spin motor 26. Thus, if the spin motor 26 operates in response to a command from the controller 90, the substrate S sucked and held in a horizontal posture on the spin base 21 rotates about the axis of rotation A1 integrally with the spin base 21 and the packing 50.

A processing liquid supplier 30 is provided to supply the processing liquid to the upper surface of the rotating substrate S. The processing liquid supplier 30 includes a nozzle 31 in such a posture that a discharge port (not shown) thereof faces downward. The nozzle 31 is connected to a nozzle mover 32 and movable between a position above an upper surface center of the substrate S, i.e. a processing position P1 (FIG. 2B), and a position P2 (FIG. 2B) separated from the substrate S. That is, the nozzle mover 32 moves the nozzle 31 to the processing position P1 in response to a command from the controller 90 for controlling each component of the substrate processing apparatus 10. If the nozzle 31 is positioned, the discharge port of the nozzle 31 faces the upper surface center of the substrate S as shown in FIG. 2A. In this state, the nozzle 31 can selectively discharge a development liquid or a rinse liquid toward the substrate S. That is, a pipe 33 extends from the nozzle 31, and a tip part thereof is branched into two branch pipes. Out of those, one branch pipe 34 is connected to a development liquid supply source (not shown), and a valve 35 is disposed in an intermediate part thereof. Further, the other branch pipe 36 is connected to a rinse liquid supply source (not shown), and a valve 37 is disposed in an intermediate part thereof. Thus, if the valves 35, 37 are respectively opened and closed in response to a command from the controller 90, the development liquid is discharged downward from the discharge port of the nozzle 31 and supplied to an upper surface Sf of the substrate S. In this way, the development processing is performed. Conversely, if the valves 35, 37 are respectively closed and opened, the rinse liquid is discharged downward from the discharge port of the nozzle 31 and supplied to the upper surface Sf of the substrate S. In this way, a rinse processing is performed.

While the development processing and the rinse processing are performed, the processing liquid is spun off from substrate S. Accordingly, a guard unit 40 is provided to surround the rotating substrate S. The guard unit 40 includes a tubular guard 41 for receiving the development liquid and the rinse liquid discharged to outside from the substrate S along an air stream generated according to the rotation of the substrate S, a cup 42 for receiving the processing liquid guided downward by the guard 41 and an outer peripheral ring 43 surrounding the guard 41 and the cup 42.

The guard 41 is vertically movable with respect to a bottom part of the chamber 11. On the other hand, the cup 42 is fixed to the bottom part of the chamber 11. Further, as shown in FIG. 2A, an elevator 44 is connected to the guard 41. The elevator 44 vertically raises and lowers the guard 41 between an upper position (position indicated by a two-dot chain line) and a lower position (position indicated by a solid line) in response to a command from the controller 90 and stops the guard 41 at an arbitrary position between the upper position and the lower position. Here, at the upper position, the upper end of the guard 41 is located above a support position where the substrate S held by the spin chuck 20 is arranged. At the lower position, the upper end of the guard 41 is located below the support position.

The controller 90 is constituted by a computer including a CPU (=Central Processing Unit), a RAM (=Random Access Memory) and the like, and controls each component of the substrate processing apparatus 10 as follows in accordance with a program stored in a storage (not shown) to perform the development processing and the rinse processing.

The controller 90 gives a loading request for the substrate S to the substrate conveyor robot 111. In response to this, the substrate conveyor robot 111 loads the substrate S onto the upper surface 211 of the spin base 21 and the packing 50 (loading step). During this loading, the annular elastic part 52 of the packing 50 contacts the lower surface Sb of the substrate S lowered toward the spin base 21 and suppresses suction leak while being elastically deformed.

FIGS. 4A to 4C schematically show the operation of the annular elastic part according to the transfer of the substrate to the spin base 21. More particularly, FIG. 4A shows a state immediately after the loading of the substrate by the substrate conveyor robot, FIG. 4B shows a state immediately after the annular elastic part contacts the lowered substrate, and FIG. 4C shows a state when the transfer of the substrate to the spin base is completed. Note that HP0, HP1 and HP2 in these figures respectively represent a height position of the substrate S immediately after the loading, a height position of the substrate S immediately after the contact of the annular elastic part 52 and a height position of the substrate S when the transfer is completed.

The substrate conveyor robot 111 moves the unprocessed substrate S to the position HP0 right above the spin base 21 while holding the substrate S by a hand (not shown) (FIG. 4). At this time, the annular elastic part 52 is not in contact with the substrate S and has a conical shape extending upward from an outer peripheral edge part of the externally fitting part 51 to an outer side. Further, the valve 24 (FIG. 2A) is closed and suction is in an OFF state.

Subsequently, the substrate conveyor robot 111 lowers the hand to a position lower than the upper surface 211 of the spin base 21. During that lowering, the lower surface Sb of the substrate S contacts the tip part of the annular elastic part 52 as shown in FIG. 4B. The controller 90 opens the suction valve 24 at this contacting position HP1 to give a suction force of the suction pump 22 to the suction grooves 212. In this way, air in a space SP surrounded by the upper surface 211 of the spin base 21, the lower surface Sb of the substrate S and the packing 50 is sucked via the suction grooves 212. The lowering of the substrate S to the spin base 21 is continued with this suction continued. During that time, the annular elastic part 52 is deformed to follow and held in close contact with the lower surface Sb of the substrate S while surrounding the lower surface center of the substrate S. Note that a timing at which the suction is transitioned to an ON state is not limited to the height position HP1. For example, suction may be started at a position lower than the height position HP1 and higher than the height position HP2 described next.

When the hand of the substrate conveyor robot 111 is lowered to a position lower than the upper surface 211 of the spin base 21, the lower surface Sb of the substrate S reaches the suction region 213 of the spin base 21 (height position HP2 in FIG. 4C). If the substrate S is warped at this point of time, a part of the lower surface center of the substrate S may be lifted from the suction region 213 and the above space SP may be present. However, suction from the space SP is continued with suction leak from the space SP kept suppressed by the packing 50. Thus, the warped substrate S is sucked, attracted to the suction region 213 and held in close contact with the suction region 213. As a result, even if the substrate S is warped, the substrate S is held on the upper surface 211 of the spin base 21 with a sufficient suction force (sucking/holding operation).

If the loading of the substrate S is completed in this way, the substrate conveyor robot 111 is retracted from the substrate processing apparatus 10. Subsequent to that, the controller 90 gives a rotation command to the spin motor 26 to rotate the substrate S integrally with the spin base 21 and the packing 50. Further, the controller 90 gives a movement command to the nozzle mover 32, and opens the valve 35 after the nozzle 31 is moved to the processing position P1. In this way, the development liquid is discharged toward the upper surface Sf of the substrate S from the nozzle 31 and the development processing is performed (processing liquid supplying step). After the development processing, the controller 90 stops the supply of the development liquid from the nozzle 31 by closing the valve 35. Subsequent to that, the controller 90 performs the rinse processing by opening the valve 37 and supplying the rinse liquid from the nozzle 31 to the upper surface Sf of the substrate S. After the end of the rinse processing, the controller 90 stops the supply of the rinse liquid from the nozzle 31 by closing the valve 37. Thereafter, the controller 90 gives a high-speed rotation command to the spin motor 26 to spin-dry the substrate S. Further, the controller 90 gives a rotation stop command to the spin motor 26 to stop the rotation of the substrate S. Furthermore, the controller 90 gives an unloading request for the substrate S to the substrate conveyor robot 111, and the processed substrate S is unloaded from the substrate processing apparatus 10 by an operation opposite to that during the loading.

As described above, according to this embodiment, the development processing is possible while the substrate S is sucked and held with a suction force capable of sufficiently withstanding the rotation of the substrate S, for example, even if the substrate S is warped.

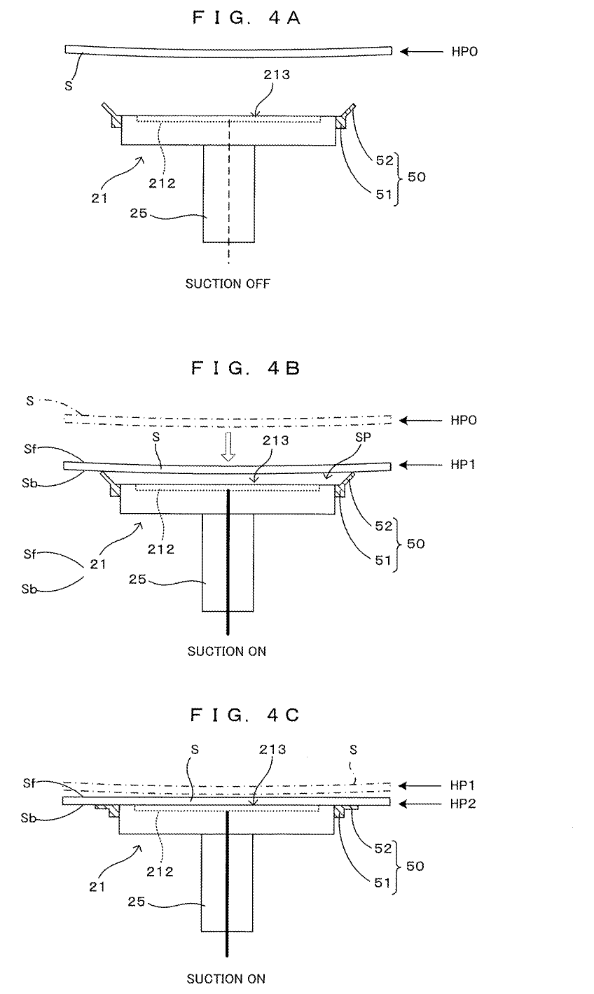

FIG. 5 is a diagram showing the configuration of a second embodiment of the substrate processing apparatus according to the invention. The second embodiment largely differs from the first embodiment in the planar shape of a spin base 21 and the shape of a packing 50. In the second embodiment, the spin base 21 is constituted by a flat plate finished into a rounded rectangular shape (rectangular shape with four rounded corners) when viewed from above. In accordance with this, the packing 50 having a rounded rectangular shape is used. Note that if an externally fitting part 51 of the packing 50 is held in close contact with a periphery 214 of the spin base 21, the use of the packing 50 having a rectangular shape is also possible.

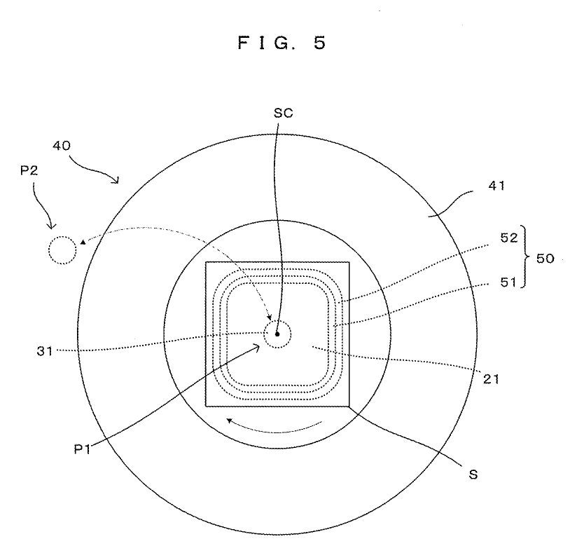

FIGS. 6A and 6B are diagrams showing the configuration of a third embodiment of the substrate processing apparatus according to the invention. The third embodiment largely differs from the first embodiment in that a support plate 53 is added, and the other configuration is basically the same as the first embodiment. Therefore, the following description is centered on points of difference and the same components are denoted by the same reference signs and not described.

A pit 532 is provided in a center of an upper surface 531 of the support plate 53. The support plate 53 is so mounted on a spin shaft 25 that the spin base 21 and the packing 50 are accommodated in the pit 532 and the upper surface 531 is flush with an upper surface 211 of the spin base 21. Thus, not only functions and effects similar to those of the first embodiment are obtained, but also the following functions and effects are further obtained. That is, if a substrate S having a central part projecting upward, i.e. convexly warped, as indicated by a one-dot chain line of FIG. 6B is lowered to the upper surface 211 of the spin base 21 by a substrate conveyor robot 111, a peripheral edge part of the substrate S contacts the upper surface 531 of the support plate 53 before a lower surface center of the substrate S contacts a suction region 213. With that contact state maintained, the lower surface center of the substrate S contacts the upper surface 211 of the spin base 21 with a delay from the contact of the peripheral edge part and is sucked. In this way, a development processing is possible while the substrate S is sucked and held with a suction force capable of sufficiently withstanding the rotation of the substrate S while correcting the warp of the substrate S.

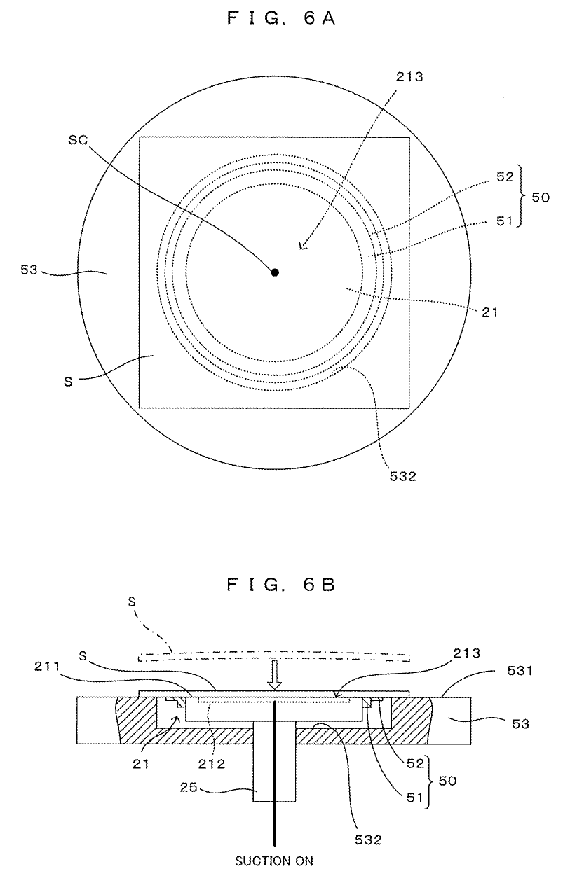

FIGS. 7A and 7B are diagrams showing the configuration of a fourth embodiment of the substrate processing apparatus according to the invention. This fourth embodiment largely differs from the third embodiment in that positioning pins 54 engageable with corners of a rectangular substrate S are provided to stand on an upper surface 531 of a support plate 53, and the other configuration is basically the same as the first embodiment. Therefore, the following description is centered on points of difference and the same components are denoted by the same reference signs and not described.

In the fourth embodiment, if the substrate S is lowered to an upper surface 211 of a spin base 21 by a substrate conveyor robot 111, four corners of the substrate S are engaged with the positioning pins 54. In this way, the substrate S is positioned at a position corresponding to disposed positions of the positioning pins 54 in a horizontal plane. In this way, a highly precise development processing can be stably performed.

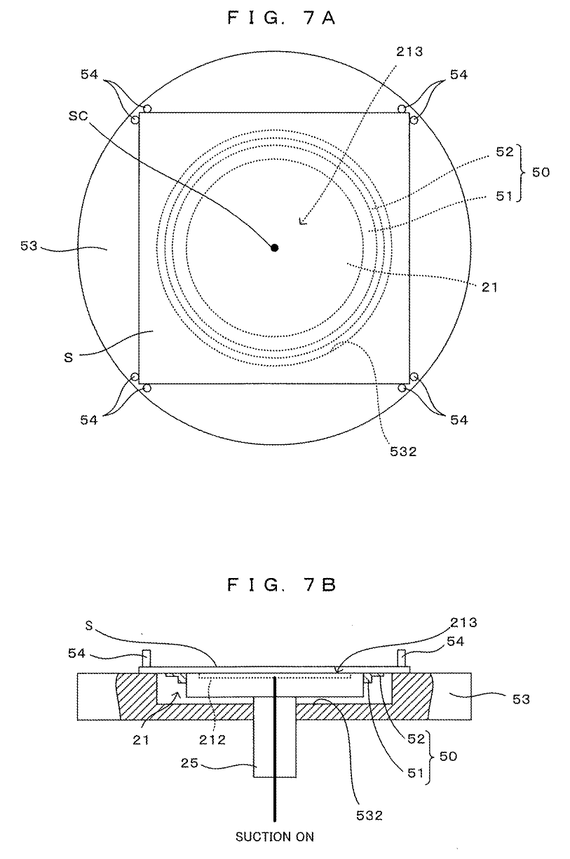

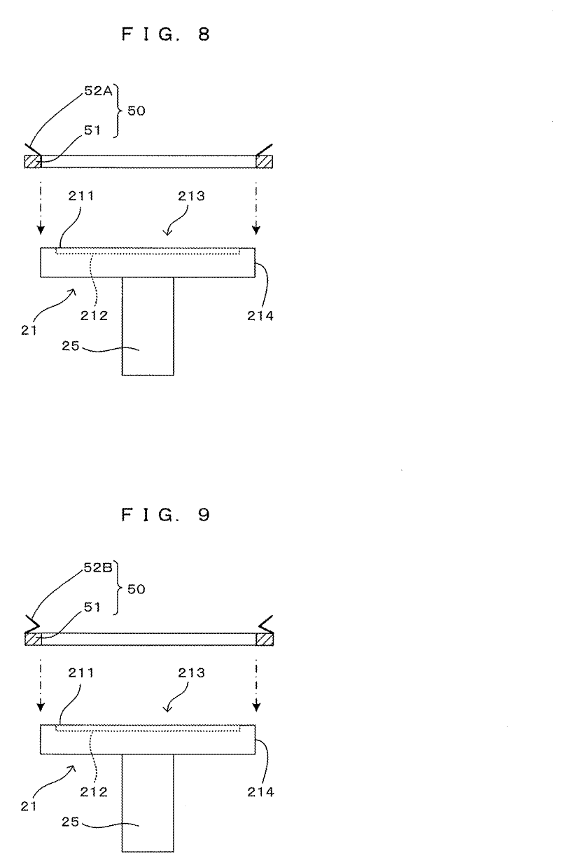

Note that the invention is not limited to the above embodiments and various changes can be added to the aforementioned embodiments without departing from the gist of the invention. For example, although the packing 50 including the annular elastic part 52 having a conical shape extending upward from the outer peripheral edge part of the externally fitting part 51 to the outer side is used, for example, in the above embodiments, the shape of the annular elastic part 52 is not limited to this. For example, a packing 50 including an annular elastic part 52A finished into a conical shape extending upward from an inner surface peripheral edge part of an externally fitting part 51 to an outer side as shown in FIG. 8 may be used (fifth embodiment). Further, a packing 50 including an annular elastic part 52B finished into a bellows shape, for example, as shown in FIG. 9 may be used (sixth embodiment).

Further, although the externally fitting part 51 and the annular elastic part 52B are integrally molded in the above embodiments, a packing 50 structured by attaching an annular elastic part 52B to an externally fitting part 51 may be used, and the annular elastic part 52B is made of an elastic material, whereas the externally fitting part 51 is made of an arbitrary material.

Further, in the above embodiments, the suction regions 213 is formed by the plurality of suction grooves 212. A suction region 213 may be formed by a plurality of suction holes. Of course, a suction region 213 may be formed by a combination of suction holes and suction grooves.

Further, in the above embodiments, the invention is applied to the substrate processing apparatus for performing the development processing. However, the invention is applicable also to a substrate processing apparatus for processing a substrate having a lower surface center sucked and held by a spin base 21 (chuck body) by supplying a processing liquid such as an etching liquid to the upper surface of the substrate while rotating the substrate.

Although the present invention has been described with reference to specific embodiments, this description is not meant to be construed in a limiting sense. Various modifications of the disclosed embodiment, as well as other embodiments of the present invention, will become apparent to persons skilled in the art upon reference to the description of the present invention. It is therefore contemplated that the appended claims will cover any such modifications or embodiments as fall within the true scope of the present invention.

This invention can be applied to substrate processing techniques in general for processing a substrate having a lower surface center sucked and held by a chuck body by supplying a processing liquid to the upper surface of the substrate while rotating the substrate.

What is claimed is:

1. A substrate processing apparatus, comprising:
a chuck body having an upper surface with a suction region configured to suction and hold a lower surface center of a substrate, the chuck body being provided rotatably about an axis of rotation while sucking and holding the substrate in the suction region;
a packing attached around the chuck body;
a rotator having a motor configured to rotate the chuck body and the packing integrally about the axis of rotation; and
a nozzle configured to supply a processing liquid to an upper surface of the substrate sucked and held on the chuck body, wherein
the packing includes an externally fitting part externally fitted around the chuck body and an annular elastic part made of an elastic material and formed from the externally fitting part to project further upward than the upper surface of the chuck body and surround the suction region, and
the annular elastic part is configured to deformed to follow and hold in close contact with a lower surface of the substrate while surrounding the lower surface center of the substrate.

2. The substrate processing apparatus according to claim 1, wherein:
the annular elastic part is finished into a conical shape extending upward from an outer peripheral edge part of the externally fitting part to an outer side.

3. The substrate processing apparatus according to claim 1, wherein:
the annular elastic part is finished into a conical shape extending upward from an inner surface peripheral edge part of the externally fitting part to an outer side.

4. The substrate processing apparatus according to claim 1, wherein:
the annular elastic part is finished into a bellows shape.

5. The substrate processing apparatus according to claim 1, further comprising a support plate provided to surround the externally fitting part externally fitted around the chuck body.

6. The substrate processing apparatus according to claim 5, wherein:
the substrate has a rectangular shape, and
a plurality of positioning pins engageable with corners of the substrate are provided to stand on the support plate at positions corresponding to the corners of the substrate sucked and held on the chuck body.

7. A substrate processing method, comprising:
(a) loading a substrate onto a packing and a chuck body;
(b) sucking and holding the substrate on the chuck body; and
(c) supplying a processing liquid to an upper surface of the substrate while rotating the chuck body, wherein:
the packing includes an externally fitting part to be externally fitted around the chuck body and an annular elastic part made of an elastic material, projecting further upward than an upper surface of the chuck body from the externally fitting part and surrounding the suction region, and
the annular elastic part is deformed to follow and held in close contact with a lower surface of the substrate while surrounding a lower surface center of the substrate in the operation (b).
